(19) United States
(12) Patent Application Publication
(10) Pub. No.: US 2008/0144261 A1
(43) Pub. Date: Jun. 19, 2008

(54) ELECTRONIC DEVICE

(75) Inventors: LU XIAO YING, BEIJING (CN); DONG ZHONG, BEIJING (CN); JERRIC P. ORTIZ, SCHAUMBURG, IL (US)

Correspondence Address: MOTOROLA INC, 600 NORTH US HIGHWAY 45, W4 - 39Q, LIBERTYVILLE, IL, 60048-5343, US

(73) Assignee: MOTOROLA, INC., LIBERTYVILLE, IL (US)

(21) Appl. No.: 11/610,400

(22) Filed: Dec. 13, 2006

(51) Int. Cl. G06F 1/16; H05K 5/02

(52) U.S. Cl. 361/680

(57) ABSTRACT

Disclosed is an electronic device 100 with a housing for electronic circuitry (110) and a flexible sheet (102) that completely covers both a touch screen region (114) and a keypad region (112) of the electronic device (100). The flexible sheet (102) is mounted to the housing and provides a front face of the electronic device (100).

### FIELD OF THE INVENTION

The present invention relates generally to an electronic device and more particularly to an electronic device with a flexible sheet that provides a front face of the electronic device.

### BACKGROUND

Many portable handheld electronic devices such as mobile telephones, have uneven surfaces and may not appear aesthetically appealing. Front faces of these devices are recessed with grooves in between the keypad region and the display region and dust may get collected over there. These grooves also create a boundary around display region and the keypad region, which may further add on to the collected dust and dirt. Many such electronic devices also have keypad bumps and raised rims that may further make them less aesthetically appealing.

### BRIEF DESCRIPTION OF THE FIGURES

In order that the invention may be readily understood and put into practical effect, reference will now be made to exemplary embodiments as illustrated with reference to the accompanying figures, where like reference numerals refer to identical or functionally similar elements throughout the separate views. The figures together with a detailed description below, are incorporated in and form part of the specification, and serve to further illustrate the embodiments and explain various principles and advantages, in accordance with the present invention where:

FIG. 1 illustrates a partially exploded view of an electronic device in accordance with an embodiment of the present invention;

FIG. 2 illustrates a more detailed exploded view of the electronic device of FIG. 1, from the top;

FIG. 3 illustrates a more detailed exploded view of the electronic device of FIG. 1, from the underside; and

FIG. 4 is a schematic diagram, illustrating circuitry and components of the electronic device of FIG. 1.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail, embodiments that are in accordance with the present invention, it should be observed that the embodiments reside primarily in combinations of device components. The device components have been represented by showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity from another entity without necessarily requiring or implying any actual such relationship or order between such entities or actions. The terms “comprises,” “comprising,” or any other variation thereof, are intended to cover a non-exclusive inclusion, such that a device that comprises a list of elements does not include only those elements but may include other elements not expressly listed or inherent to such devices. An element proceeded by “comprises . . . a” does not, without more constraints, preclude the existence of additional identical elements in the device that comprises the element.

In one aspect the present invention provides an electronic device comprising a housing within which is housed an electronic circuitry. There is also a flexible sheet completely covering both a touch screen region and a keypad region of the electronic device, the flexible sheet being mounted to the housing and providing a front face of the electronic device.

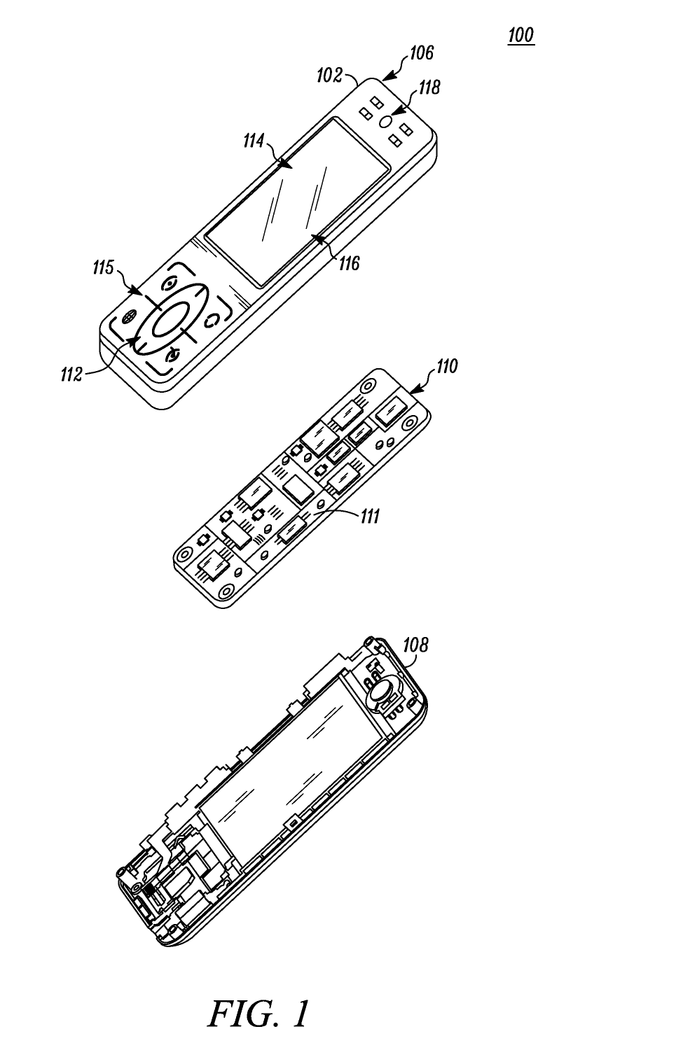

FIG. 1 illustrates a partially exploded view of an electronic device 100 in accordance with an embodiment of the present invention. The electronic device 100 includes a housing, electronic circuitry 110 mounted to a substrate 111 such as a Printed Circuit Board (PCB) and a flexible sheet 102.

The housing comprises a front housing 106 and a back housing 108. The front housing 106 has the flexible sheet 102 which is a hard coated polyester film. The flexible sheet 102 is mounted on the front housing 106, wherein the flexible sheet 102 sheet solely forms the front face of the electronic device 100 leaving the front face of the electronic device 100 flat. The flexible sheet 102 completely covers both a touch screen region 114, a keypad region 112. The flexible sheet 102 also covers a speaker region 118 of the electronic device 100. The keypad region 112 has a keypad 115, displaying keypad keys that identify commands for controlling the electronic device 100. Also, the touch screen region 114 overlays a touch screen assembly 116, and the flexible sheet 102 also covers a speaker region 118 of the electronic device 100.

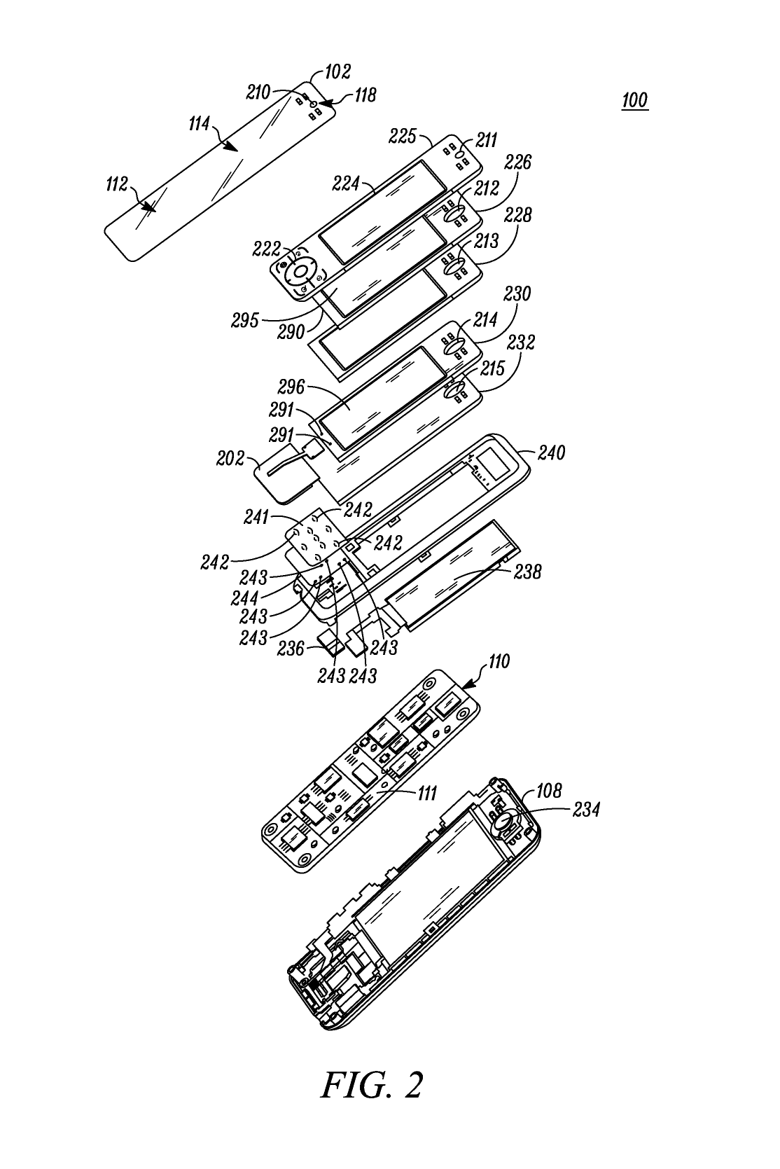

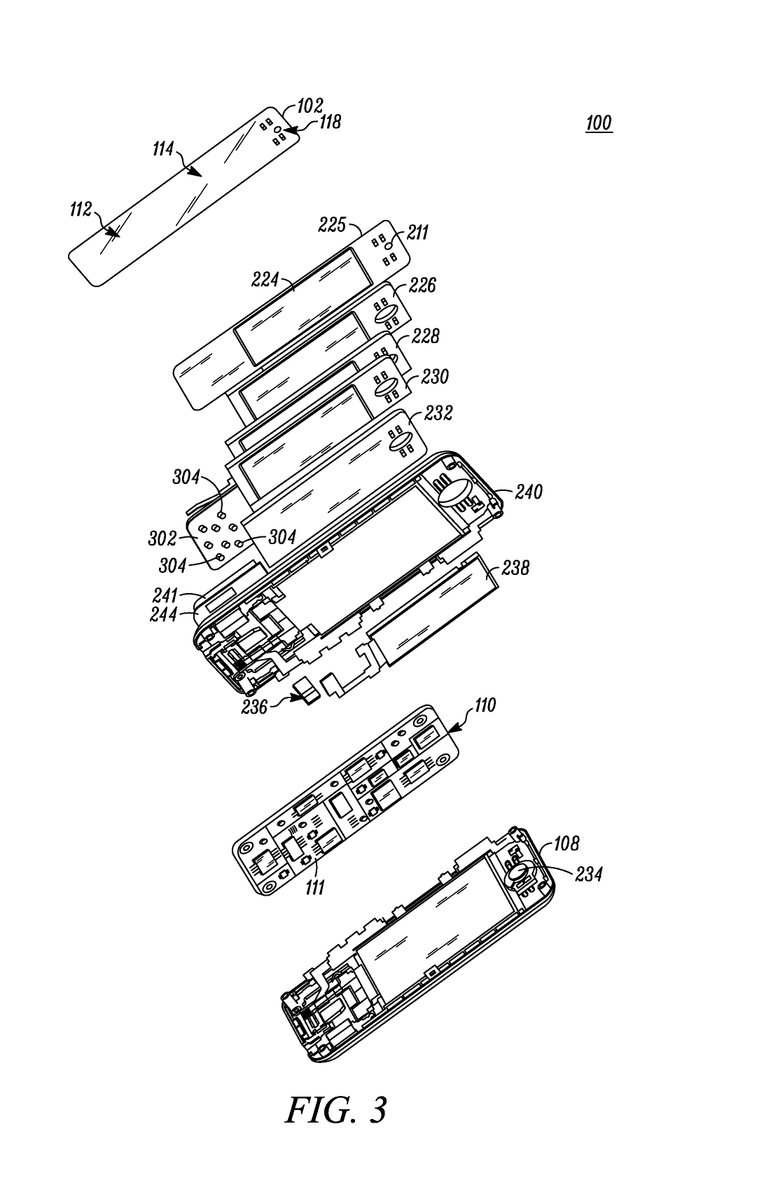

FIG. 2 and FIG. 3 illustrate more detailed exploded, respective top and underside views of the electronic device 100. The electronic device 100 includes the flexible sheet 102, a printed film 225 beneath the flexible sheet 102, a top layer 226 beneath the printed film 225 and a bottom layer 230. Typically the top layer 226 and bottom layer 230 are each typically formed from a flexible transparent sheet of plastic polyester. A spacing gasket 228 with some adhesive on each side of the spacing gasket 228 wherein the spacing gasket 228 is sandwiched between the top layer 226 and the bottom layer 230 and creates a space between the top layer 226 and the bottom layer 230. A plastic base 232 supports the top layer 226, the bottom layer 230, the spacing gasket 228, the printed film 225 and the flexible sheet 102. The electronic device 100 further includes a speaker 234, a microphone 236, a display 238 in the form of a Liquid Crystal Display (LCD) disposed below the plastic base 232, a frame 240 forming part of the front housing 106, the electronic circuitry 110 and the back housing 108.

The flexible sheet 102 is mounted on the printed film 225, wherein the printed film 225 has markings printed thereon and the flexible sheet 102 is transparent. The flexible sheet 102, the printed film 225, top layer 226, spacing gasket 228 and bottom layer 230 have respective aligned apertures 210 to 215 that are aligned with an active face of a speaker 234 that is mounted to the front housing 106. In another embodiment, there is no printed film 225 and the markings are printed on the rear face of the flexible sheet 102. The markings identify keys 222 of the keypad 115 in the keypad region 112 and also provide a boundary 224 around the touch screen region 114.

The top layer 226, the spacing gasket 228, the bottom layer 230, the plastic base 232 and the display 238 together form the touch screen assembly 116. The top layer 226 and the bottom layer 230 have a pair of respective terminals 290, 291 and respective regions of electrically resistive properties 295,296 each of the pair of terminals being in electrical connection with a respective one of the regions of electrically resistive properties 295,296. As will be apparent to a person skilled in the art, the regions of electrically resistive properties 295,296 provide for detection of X and Y co-ordinate touch screen detection when a force is applied thereto. The regions of electrically resistive properties 295,296 are oppositely facing and are provided by an Indium Tin Oxide (ITO) coating disposed on the opposing faces of the top layer 226 and the bottom layer 230. Thus, when a command is to be entered onto the touch screen assembly 116, a force is required to be applied to a selected area of the touch screen region 114 of the flexible sheet 102. The top layer 226 provides an x-coordinate of the touch screen assembly 116, in response to a force applied on the touch screen region 114. Similarly, the bottom layer 230 provides a y-coordinate of the touch screen assembly 116, in response to a force applied on the touch screen region 114. The spacing gasket 228 located between the top layer 226 and the bottom layer 230 is used for creating space between the top layer 226 and the bottom layer 230.

Below and aligned with the keypad 115 is a membrane 202, and extending from an underside of the membrane 202 is an array of plungers 304. Underneath and aligned with the membrane 202 is a flexible sheet 241 on which are formed an array of domes 242. The membrane 202 is a rubberized injection molded keypad and the array of plungers 304 is aligned and adjacent with the array of domes 242. Each dome in the array of the domes 242 has a concave conductive surface aligned and adjacent with switch contact pairs 243 disposed on a switch contact support substrate 244. To actuate switches in the keypad region 112, a force is required to be applied to a selected area of the keypad region 112 of the flexible sheet 102. All the above layers, viz. the membrane 202, the keypad 115, array of domes 242, the plungers 304, and the switch contact support substrate 244 combine together to form a tactile keypad assembly.

The frame 240 has a recessed rim which is used to support all the above layers, viz. the flexible sheet 102 which overlays the printed film 225, the top layer 226 and the bottom layer 230 which are separated by the spacing gasket 228, and the last layer is the plastic base 232. The speaker 234 is placed beneath the speaker region 118 of the flexible sheet 102, aligned and adjacent with the speaker region 118.

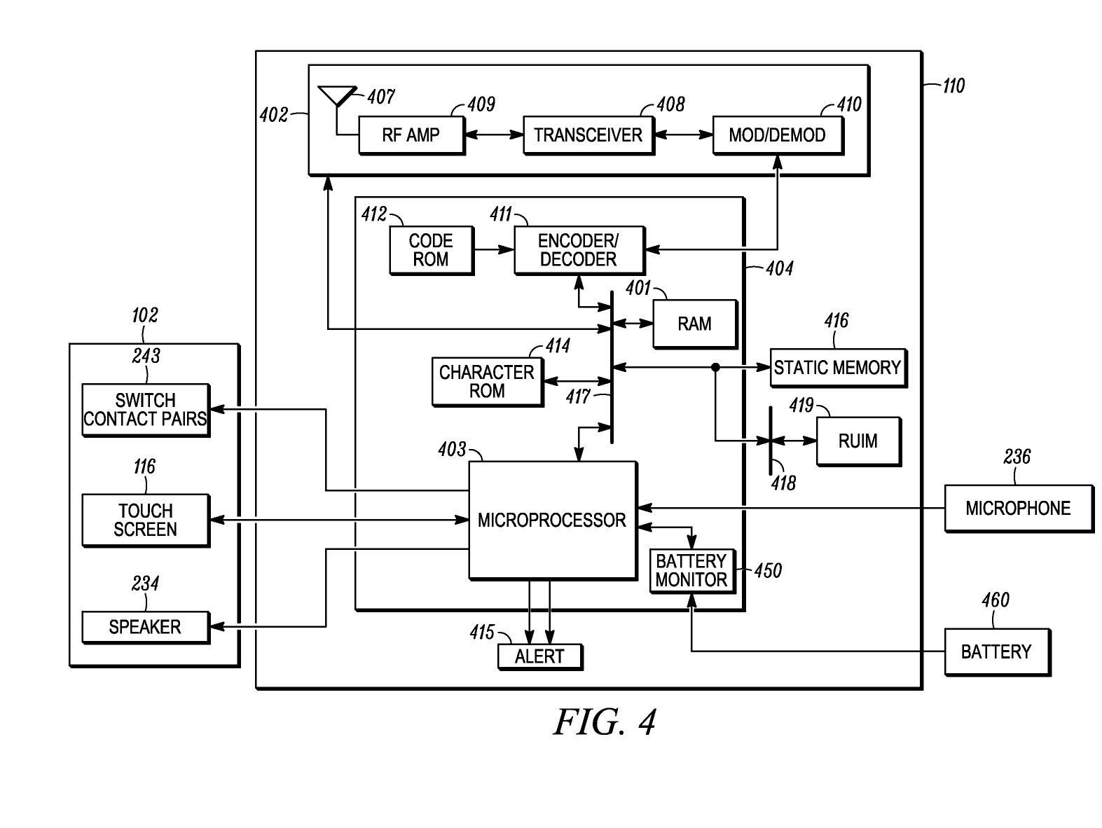

Referring to FIG. 4, there is a schematic diagram illustrating an electronic device 100, typically a wireless communications device, in the form of a mobile station or mobile telephone comprising a radio frequency communications unit 402 coupled to be in communication with a processor 404. The electronic device 1100 includes the touch screen assembly 116 and the switch contact pairs 243. The battery monitor 450, touch screen assembly 116, switch contact pairs 243 and alert module 415 are coupled to be in communication with the processor 404.

The processor 404 includes an encoder/decoder 411 with an associated code Read Only Memory (ROM) 412 for storing data for encoding and decoding voice or other signals that may be transmitted or received by the electronic device 100. The processor 404 also includes a micro-processor 403 coupled, by a common data and address bus 417, to the radio frequency communication unit 402, the encoder/decoder 411, a character Read Only Memory (ROM) 414, a Random Access Memory (RAM) 401, a static programmable memory 416 and a Removable User Identity Module (RAM) interface 418. The static programmable memory 416 and a RUIM card 419 (commonly referred to as a Subscriber Identity Module (SIM) card), operatively coupled to the RUIM interface 418, each can store amongst other things, Preferred Roaming Lists (PRLs), subscriber authentication data, selected incoming text messages and a Telephone Number Database (TND phonebook) comprising a number field for telephone numbers and a name field for identifiers associated with one of the numbers in the name field. The RUIM card 419 and static programmable memory 416 may also store passwords for allowing accessibility to password-protected functions on the electronic device 100.

The micro-processor 403 has ports for coupling to the touch screen assembly 116, the auxiliary keys and the alert module 415. Also, micro-processor 403 has ports for coupling to a microphone 236 and a speaker 234 that are integral with the electronic device.

The character Read Only Memory 414 stores code for decoding or encoding text messages that may be received by the radio frequency communication unit 402. In this embodiment the character Read Only Memory 414, RUIM card 419, and static programmable memory 416 may also store Operating Code (OC) for the micro-processor 403 and code for performing functions associated with the mobile telephone. There is also a battery 460 for providing power to the electronic device 100 to power the processor 404 and optional modules such as keypad lights, display screen backlights and the radio frequency communication unit (power connections not shown) and a monitor input of the battery monitor 450 is coupled to the battery 460.

The radio frequency communication unit 402 is a combined receiver and transmitter having an antenna 407. The radio frequency communication unit 402 has a transceiver 408 coupled to the antenna 407 via a radio frequency amplifier 409. The transceiver 408 is also coupled to a combined modulator/demodulator 410 that couples the radio frequency communication unit 402 to the encoder/decoder 411 of processor 404.

Advantageously, the present invention provides an electronic device without groves between the display region and keypad region. Further, the present invention eliminates groves creating a boundary around the display region thereby alleviating the problem of dust collecting in such groves whilst providing an aesthetically appealing front face.

In the foregoing specification, specific embodiments of the present invention has been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims.

We claim:

1. An electronic device comprising:
a housing within which is housed an electronic circuitry; and
a flexible sheet completely covering both a touch screen region and a keypad region of the electronic device, the flexible sheet being mounted to the housing and providing a front face of the electronic device.

2. The electronic device of claim 1, wherein the flexible sheet also covers a speaker region of the electronic device, wherein there is an aperture in an area of the flexible sheet that covers the speaker region.

3. The electronic device of claim 1, wherein the flexible sheet is transparent.

4. The electronic device of claim 1, wherein in use to actuate switches in the keypad region, a force is required to be applied to a selected area of the keypad region of the flexible sheet.

5. The electronic device of claim 1, wherein to enter a command at a touch screen assembly, a force is required to be applied to a selected area of the touch screen region of the flexible sheet.

6. The electronic device of claim 3, wherein there is a printed film beneath the flexible sheet.

7. The electronic device of claim 1, wherein the flexible sheet has markings printed on its rear face thereof.

8. The electronic device of claim 6, wherein the printed film has markings printed on it.

9. The electronic device of claim 8, wherein the markings identify a keypad in the keypad region.

10. The electronic device of claim 8, wherein the markings provide a boundary around the touch screen region.

11. The electronic device of claim 1, wherein the flexible sheet solely forms the front face of the electronic device.

12. The electronic device of claim 1, wherein the housing comprises a front housing and a back housing.

13. The electronic device of claim 12, wherein the front housing comprises a frame with a recessed rim for supporting the flexible sheet.

14. The electronic device of claim 1, wherein the electronic circuitry comprises a radio frequency communication unit and a processor.

15. The electronic device of claim 9, further comprising a membrane with an array of plungers, wherein the membrane is aligned and adjacent with the keypad.

16. The electronic device of claim 15, further comprising an array of domes, wherein the array of domes is aligned an adjacent with the membrane thereby, providing a tactile keypad assembly.

17. The electronic device of claim 1, wherein the touch screen region overlays a touch screen assembly beneath the touch screen region, the touch screen assembly being aligned and adjacent with the touch screen region.

18. The electronic device of claim 2, wherein the speaker region comprises a speaker beneath the speaker region, the speaker being adjacent and aligned with the aperture.
